(19) United States
(12) Patent Application Publication
(10) Pub. No.: US 2010/0288333 A1
(43) Pub. Date: Nov. 18, 2010

(54) HEAT DISSIPATING PROTECTIVE SHEETS AND ENCAPSULANT FOR PHOTOVOLTAIC MODULES

(76) Inventors: Marina Temchenko, Swampscott, MA (US); David William Avison, Townsend, MA (US); Frank A. Mannarino, Medway, MA (US); Samuel Lim, Lynn, MA (US)

Correspondence Address: NORRIS MCLAUGHLIN & MARCUS, P.A., 721 ROUTE 202-206, P.O.BOX 5933, BRIDGEWATER, NJ, 08807-5933, US

(21) Appl. No.: 12/779,210

(22) Filed: May 13, 2010

Related U.S. Application Data
(60) Provisional application No. 61/178,210, filed on May 14, 2009.

(51) Int. Cl. H01L 31/052; H01L 31/042

(52) U.S. Cl. 136/246; 136/244

(57) ABSTRACT

A photovoltaic module that resists or reduces unwanted increases in temperature of the photovoltaic cells encapsulated within the module is provided. This is accomplished by incorporating materials into module components that operate to direct heat away from the solar cells that are within the modules. One or more phase change materials are incorporated into the polymer layer of the backsheet that is position closest to the solar cells. Thermally conductive materials may be incorporated into the layers and/or module components closer to the outside of the module. These materials can be used separately or in conjunction with each other.

### CROSS REFERENCE TO RELATED APPLICATION

This application claims the benefit of U.S. Provisional Patent Application No. 61/178,210, filed May 14, 2009, the entirety of which is hereby incorporated by reference into this application.

### BACKGROUND OF THE INVENTION

1. Field of the Invention

The present invention relates to photovoltaic modules. More specifically the present invention related to the protective sheets and encapsulants of photovoltaic modules.

2. Description of Related Art

Solar energy utilized by photovoltaic modules is among the most promising alternatives to the fossil fuel that is being exhausted this century. However, production and installation of the photovoltaic modules remains an expensive process. Typical photovoltaic modules consist of glass or flexible transparent front sheet, solar cells, encapsulant, protective backing sheet, a protective seal which covers the edges of the module, and a perimeter frame made of aluminum which covers the seal. As illustrated in FIG. 1, a front sheet 10, backing sheet 20 and encapsulant 30 and 30′ are designed to protect array of cells 40 from weather agents, humidity, mechanical loads and impacts. Also, they provide electrical isolation for people's safety and loss of current. Protective backing sheets 20 are intended to improve the lifecycle and efficiency of the photovoltaic modules, thus reducing the cost per watt of the photovoltaic electricity. While the front sheet 10 and encapsulant 30 and 30′ must be transparent for high light transmission, the backing sheet typically has high opacity for aesthetical purposes and high reflectivity for functional purposes. Light and thin solar cell modules are desirable for a number of reasons including weight reduction, especially for architectural (building integrated PV) and space applications, as well as military applications (incorporated into the soldier outfit, etc). Additionally light and thin modules contribute to cost reduction. Also reduction in quantity of consumed materials makes the technology “greener”, thus saving more natural resources.

One means to manufacture light and thin solar cells is to incorporate light and thin backing sheets. The backside covering material however, must also have high moisture resistance to prevent permeation of moisture vapor and water, which can cause rusting in underlying parts such as the photovoltaic element, wire, and electrodes, and damage solar cells. In addition, backing sheets should provide electrical isolation, mechanical protection, UV protection, adherence to the encapsulant and ability to attach output leads.

Currently used protective backing sheets are typically (but not always) laminates. FIG. 2 provides an illustration of a typical laminate backing sheet 20. The laminate consists of films of polyvinylfluorides 22, which is most commonly Tedlar®, polyesters (PET) 24, and copolymers of ethylene vinyl acetate (EVA) 26 as key components. The EVA layer 26 bonds with the encapsulant layer 30 in the module and serves as a dielectric layer and has good moisture barrier properties. It is dimensionally stable.

Photovoltaic devices (PV) are characterized by the efficiency with which they can convert incident solar power to useful electric power. Devices utilizing crystalline or amorphous silicon have achieved efficiencies of 23% or greater. However, efficient crystalline-based devices are difficult and expensive to produce. For example, the amount of silicon needed for 1 kW of module output power is approximately 20 kg, and the cost for 1 kg of electronic grade silicon is estimated to be about $20.00. In order to produce low-cost power, the solar cell must operate at high efficiency.

Photovoltaic cells (or alternatively referred to as solar cells) are very sensitive to the temperature. It has been determined that at the operating temperature of 64° C., there was a decrease of 69% in the efficiency of the crystalline silicone solar cell compared with that measured at standard test conditions (25° C.). (A. Q. Malik, Salmi Jan Bin Haji Damit “Outdoor testing of single crystal silicon solar cells” Renewable energy, Volume 28, Issue 9, July 2003, p 1433-1445).

This temperature dependence can be expressed mathematically. The temperature dependence of band gap energy is modeled by the following equation:

$${E}_{G} ( T ) = {E}_{G} ( 0 ) - \frac{α {T}^{2}}{T + β}$$

where E_{G}(0) is the energy band gap at T=0, α and β are the constants specific to each semiconductor.

Since the increase of temperature always results in a decrease of the efficiency of the photovoltaic conversion, it is necessary to keep the temperature of solar cells as close to its peak operating temperature as possible in order to improve the conversion efficiency. The peak operating temperature is different for different cells but all currently available photovoltaic cells will heat up above its peak operating temperature during the day in full sun. Accordingly, it is often necessary to apply external means to reduce the temperature of the cells or otherwise prevent the temperature from rising too high. One way this has been accomplished is to apply cooling devices to the solar cells, which in turn requires energy.

It would be desirable to find a more efficient means of heat management of solar cells in order to increase the conversion efficiency of solar cells. It would be desirable to have a means to manage the heat of solar cells that did not require external cooling device or source.

### SUMMARY OF THE INVENTION

The present invention provides method and device for the improvement of conversion efficiency of solar cells. The conversion efficiency is accomplished by adding heat dissipating properties to the back sheets, front covers and/or the encapsulant of solar cells. This helps control the temperature of the solar cells which in turn increases (or maintains) the conversion efficiency of the cells. More specifically, improved back sheets, front covers, and encapsulants functions to prevent the solar cells from undesirable temperature increases, thereby preventing a decrease in efficiency due to overheating.

In one embodiment, the heat dissipating properties are added to the backsheet or encapsulant by incorporation of phase change material (PCM) into the backsheet or encapsulant. Preferably, the PCM is incorporated in a component nearest to the solar cells. In a backsheet constructed of multiple layers, the PCM is incorporated in the layer adjacent to the solar cells.

In another embodiment, the heat dissipating properties of the PVMs are achieved by incorporation of thermally conductive fillers in one or more of the components that surround the solar cells, i.e. the backsheet, encapsulant and front cover. This can be done either alone or in conjunction with the incorporation of PCM. In a preferred embodiment, the thermally conductive fillers are incorporated into the layer adjacent to the layer containing PCM and into the front cover.

In another embodiment, the heat dissipating properties are achieved by the addition of thermally conductive coatings. Coatings, for example, of boron nitride, metals, metals oxides, titanium nitride, etc., applied on the different layers of backsheet or on the encapsulant function to conduct heat away from the solar cells. In addition or alternatively, thermally conductive adhesives and tie layers can be used alone or in conjunction with the other methods described herein in the construction of photovoltaic modules.

In yet another embodiment heat rejecting coatings are applied on the outer layer of the backsheet and/or front sheet to provide heat dissipating properties and control the temperature of the solar cells. Again such heat rejecting coating can be used alone or in conjunction with the other methods described herein in the construction of photovoltaic modules.

### BRIEF DESCRIPTION OF THE DRAWINGS

For a better understanding of the present invention, reference may be made to the accompanying drawings.

FIG. 1 represents an expanded view of the components of a typical photovoltaic module.

FIG. 2 represents one embodiment of the typical backing sheet.

FIG. 3 is the graph showing the typical behavior of phase change material.

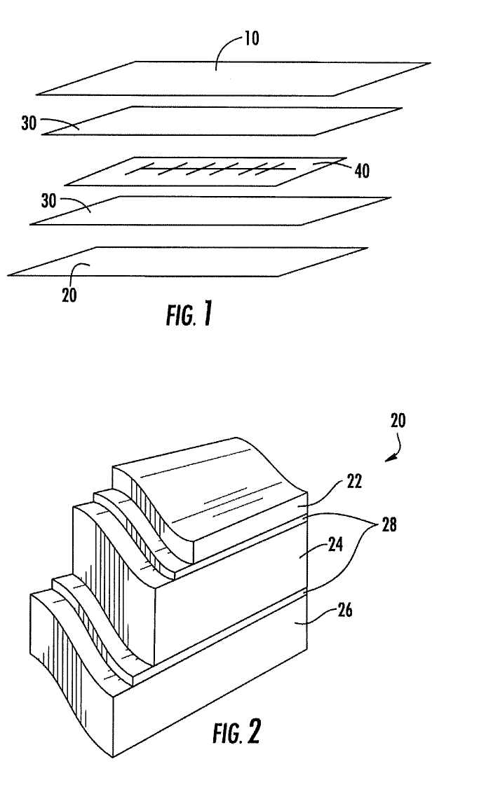

### DETAILED DESCRIPTION

### Overview

A photovoltaic module that resists or reduces unwanted increases in temperature of the photovoltaic cells encapsulated within the module is provided. This is accomplished by incorporating materials into module components that operate to direct heat away from the solar cells that are within the modules.

Preferably, one or more phase change materials are incorporated into the polymer layer of the backsheet (or alternatively referred to as backing sheet) that is positioned closest to the solar cells. Thermally conductive materials may be incorporated into the layers and/or module components closer to the outside of the module. These materials can be used separately or in conjunction with each other.

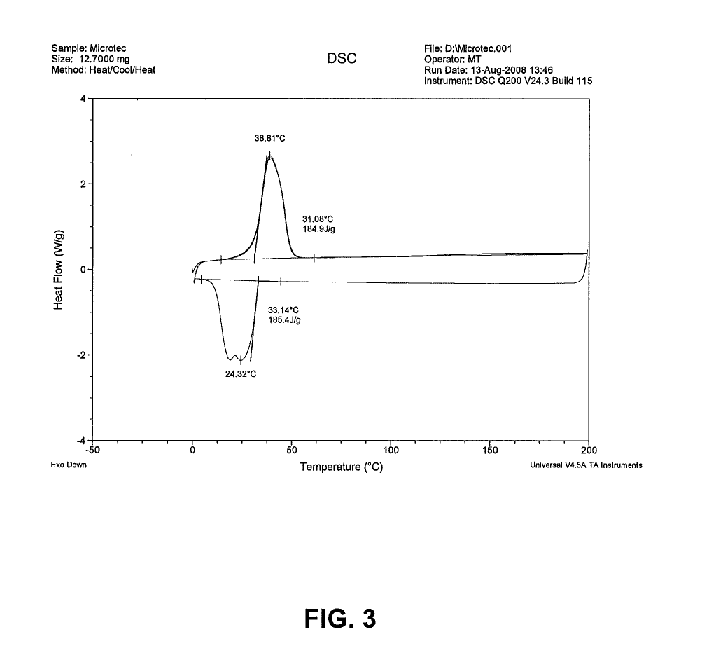

Phase change materials are materials that undergo phase transitions from liquid to solids, reversibly. The typical behavior of PCM is depicted in FIG. 3. At the temperature of the transition, the material absorbs heat while melting and releases heat while crystallizing. These materials include, but are not limited to, paraffines, fatty acids, salt hydrates, and eutectics and microencapsulated PCM, chemically modified PCM, etc.

Heat Dissipating Backsheets, and Encapsulants

In one embodiment, one or more phase change materials are incorporated into the backing sheet or encapsulant of a photovoltaic module. When the phase change material melts, (or transitions from the solid to the liquid state), it is an endothermic process, so the material will absorb heat. When the liquid material crystallizes going to the solid state, it is the exothermic process so it will release heat. When incorporated into a photovoltaic module, the phase change material operates to absorb heat before it reaches the cells and release it away from the cell. As a result, temperature increases of the solar cells are suppressed without the use of external cooling devices.

When a module that incorporates phase change material in the backing sheet or encapsulant begins to reach a certain temperature, the phase change material will absorb heat before the heat reaches the solar cells.

The choice of phase change material depends on a number of factors. The most important factor in choosing a phase change material is that the material or materials have a transition (melting) temperature that is less than or around the same temperature as the peak operating temperature of the specific solar cells used in the PV module.

The backing sheet of the present invention can be made of any material, usually polymers, typically used to produce backing sheet. In one embodiment, the combination of one or more phase change materials is incorporated into a polymer matrix to form a film or sheet. In another embodiment, backing sheet is prepared by applying a coating containing one or more phase change materials to a polymer film. Numerous arrangements are possible. The key property of the backing sheet is that it incorporates a phase change material. Preferably the phase change material is in close proximity to the solar cells. As discussed further below, this is easily and simply accomplished in one embodiment by incorporating a phase change material into the layer of the backing sheet closest to the solar cells.

In many photovoltaic modules, the backing sheet or front cover is a laminate comprising more than one layer of film laminated together. When a laminate is used, the phase change material is preferably incorporated into the layer that is closer to the solar cells. Alternatively, the phase change material can comprise the layer closest to the solar cells, or the phase change material can be applied to the film or layer closest to the solar cells by way of a coating containing the material.

The phase change material will absorb the heat and transfer (release it) to the next layer which preferably has heat dissipating properties thereby moving it away from the solar cells. When the inventive backing sheets are used as protective backing sheets for PV modules, they function to avoid unwanted increases in the temperature of the solar cells and remain aesthetically satisfactory over extended use, provide effective protection for the current generated in the PV module and exhibit high dielectric strength.

In one embodiment, the laminate comprises (a) a first outer layer of weatherable film; (b) at least one mid-layer; and (c) a second outer layer (alternatively referred to as an inner layer). Preferably the phase change material is incorporated into the inner layer or even applied to the surface of the inner layer. When used in a photovoltaic module, the first outer layer of the laminate is exposed to the environment, and the inner layer is exposed to or faces the solar cells and solar radiation. The inner layer can be made of any material, but is typically made of one or more polymers. In one example, inner layer is made of ethylene vinyl acetate (EVA). The vinyl acetate content of the EVA is generally about from 2 to 33 weight percent and preferably from 2 to 8 weight percent. In another example the inner layer is matrix of an organic solvent soluble and for water dispersible, crosslinkable amorphous fluoropolymers containing phase change materials. Particular embodiments include a copolymer of tetrafluoroethylene (TFE) and hydrocarbon olefins with reactive OH functionality. The layer may further include a crosslinking agent mixed with the fluorocopolymer.

Crosslinking agents are used in the formation of the protective coatings include to obtain organic solvent insoluble, tack-free film. Preferred crosslinking agents include but are not limited to DuPont Tyzor® organic titanates, silanes, isocyanates, melamine, etc. Aliphatic isocyanates are preferred to ensure weatherability as these films are typically intended for over 30 years of outdoor use.

In an alternate embodiment, the composite heat dissipating properties of the laminate is increased by including in the laminate backing sheet a layer or layers capable of dissipating heat. For example, in the laminate described above, the first outer layer and/or mid layer are also incorporated with one or more thermally conductive fillers. Such an arrangement, when used in conjunction with phase change materials in the inner layer, results in a greater net heat dissipation and greater module efficiency and power output. Alternatively, the use of thermally conductive fillers can be effective by itself as a means to dissipate heat from the PV module. In addition to thermally conductive fillers, thermally conductive adhesives, tie layer and or coatings can also be utilized to further increase the net heat dissipating properties of the laminate.

Thermally conductive fillers include, but not limited to, powders and nanoparticles of boron nitride, metal oxides, metals, graphite, calcium boride, titanium nitride, aluminum nitride, titanium diboride, silicon carbide, carbon nanotubes, and their combination. Boron nitride powders and nanoparticles are known to improve the thermal conductivity of polymers. They also possess excellent electrical insulation properties. Thermally conductive coatings include but are not limited to boron nitride, metals, metals oxides, titanium nitride. These coating can be applied on one or more of the different layers of backsheet.

The individual layers of the laminates of the present invention can be adhesively bonded together. A thermally conductive adhesive can optionally be used. The specific means of forming the laminates of the present invention will vary according to the composition of the layers and the desired properties of the resulting laminate, as well as the final application for which the backing sheet is to be used.

In addition to the laminate, the other components of a photovoltaic module may also include materials that enhance the heat dissipation of the module. For example, the encapsulant and/or front cover may also include thermally conductive fillers. Of course, the front cover must transmit solar radiation of certain wavelengths in order for the solar cell to operate. Accordingly, the choice of filler in terms of type of filler, particle size, concentration, etc. would be guided by this consideration when preparing a front cover.

Another method of controlling the heat of the module, either alone or in combination with one or more of the other methods described herein is to apply a heat rejecting coating on the outer layer of the backing sheet or on the front cover. The same principle applies in selecting a heat rejecting coating as in choosing a thermally conductive material. That is, the coating operates to prevent overheating of the solar cells while at the same time not hindering the performance of the cell. The coating should not compromise the performance of the back sheet or the front cover. So a heat rejecting coating on the front cover must still permit the appropriate amount and type of solar radiation through the front cover to the solar cells.

Combination with Other Methods for Increasing Efficiency

The materials and methods of dissipating heat of a photovoltaic module can be combined with other methods for increasing the efficiency of the photovoltaic module. For example, one or more white pigments and/or one or more photo luminescent materials can incorporate into the polymer matrix of the film or films used in the backing sheet. In one embodiment, the backsheet laminate comprises an inner layer that is photoluminescent and contains phase change material. The photoluminescent layer is capable of absorbing a wide range of solar wavelengths (UV, IR and visible) and converting the absorbed solar radiation into photons whose energy is at or greater than the band gap energy of corresponding semiconductor.

Optionally, the composite reflectance of the backsheet laminate is increased by including more than one layer capable of absorbing solar radiation of various wavelengths and converting the absorbed solar radiation into photons with energy at or greater than the band gap energy of corresponding semiconductor. For example, the first outer layer and/or mid layer are also incorporated with one or more white pigments and one or more photo luminescent materials in the same manner as the inner layer. Such an arrangement results in a greater increase in net reflectance and greater module efficiency/power output. Optionally, the addition of thermally conductive fillers, adhesives, tie layers are also incorporated into the first outer layer and/or mid layer as described above.

Any white pigment may be used for increasing the reflectivity of the backing sheet. For example, titanium dioxide, (Ti-Pure® series of titanium dioxide made by DuPont for example), calcium carbonate, lithopone, zinc sulfate, aluminum oxide, boron nitride, etc. can be used depending on the application. Again, depending on the application, the white pigment is typically added at to the polymer of the inner layer to contain about 20-60 weight percent. Of these, titanium dioxide is preferred for its ready availability.

Preferably, photoluminescent materials are added to the inner layer in combination with the white pigment. These materials however can be added without the pigment and/or can be added to more than one layer of the laminate or all layers of backing sheet. The addition of photoluminescent material to multiple layers increases the net reflectance of the laminate. Photoluminescence is the complete process of absorption and re-emission of light. Ordinary pigments absorb and reflect energy, while photoluminescent materials absorb, reflect and re-emit. They are typically added to the inner layer to contain about 0.01-30.0 weight %.

One example of photoluminescent material is optical brighteners. Optical brighteners fluoresce and are particularly preferred for use in the backing sheet. Optical brighteners, such as Ciba® UVITEX® OB, absorb UV light and re-emit it as a visible light. For different semiconductors with different energy gaps, other photoluminescent materials with matching characteristics are easily identified and incorporated into the backing sheet.

Another example of photoluminescent materials are BASF manufactured dyes (coumarine and perylene based) or Lightleader Co., Ltd manufactured materials. For example, YG-1F. A typical excitation (left) and photoluminescence spectra (right) is depicted in FIG. 3. Alternatively, non linear optic materials such as metal fluoride phosphors may be used. These phosphors may be used for upcoversion of infrared (IR) radiation to various forms of visible light.

In yet another embodiment, the inner layer is matrix of an organic solvent soluble and/or water dispersible, crosslinkable amorphous fluoropolymers containing phase change materials and white pigments and/or photo luminescent materials. Particular embodiments include a copolymer of tetrafluoroethylene (TFE) and hydrocarbon olefins with reactive OH functionality. The layer may further include a crosslinking agent mixed with the fluorocopolymer.

In an alternate embodiment, white pigmented polyvinyl fluoride (such as that commercially available from DuPont as Tedlar® polyvinyl fluoride) is used as the inner layer. To achieve the desired photoluminescence, the layer is coated with thin light reflecting film containing photo luminescent materials, and optionally white pigment. Preferably, the white coating contains from 40 to 50 weight % of white pigment and 0.01-2.0 weight % fluorescent whitening agents and can optionally contain phase change materials.

The matrix for the thin light reflecting coating can be selected from a wide variety of polymers, such as acrylic polymers, urethane, polyesters, fluoropolymers, chlorofluoropolymers, epoxy polymers, polyimides, latex, thermoplastic elastomers, and ureas. The thin light reflecting coating can be applied to the second outer layer by any of a variety of methods known to those skilled in the art of film coating manufacture. Preferred methods include coating application by spraying, dipping and brushing.

The coating can be applied to any backing sheet to impart the desired photoluminescence. That is, any backing sheet known in the art can be converted to a power boosting backing sheet by coating the backing sheet with a photoluminescent coating, preferably one that contains white pigment. A primary consideration in choosing the specific photoluminescent material is to match the peak emission wavelength (i.e., at or near) with a band gap of the semiconductor material within the intended photovoltaic device.

The backing sheet may also include additional layers. The additional layers may be applied to the fluorocopolymer layer with or without adhesive. The optional additional layers may include, for example, one or of a polyester, EVA, polycarbonate, polyolefin, polyurethane, liquid crystal polymer, aclar, aluminum, sputtered aluminum oxide polyester, sputtered silicon dioxide polyester, sputtered aluminum oxide polycarbonate, sputtered silicon dioxide polycarbonate, sputtered aluminum oxide fluorocopolymer with crosslinkable functional groups, sputtered silicon oxide fluorocopolymer with crosslinkable functional groups.

There will be various modifications, adjustments, and applications of the disclosed invention that will be apparent to those of skill in the art, and the present application is intended to cover such embodiments. Although the present invention has been described in the context of certain preferred embodiments, it is intended that the full scope of these be measured by reference to the scope of the following claims.

The disclosures of various publications, patents and patent applications that are cited herein are incorporated by reference in their entireties.

What is claimed is:

1. A backing sheet for a photovoltaic module comprising:
phase change material incorporated into the backing sheet.

2. The backing sheet of claim 1 wherein the backing sheet comprises at least an inner layer and an outer layer and the phase change material is incorporated into the inner layer.

3. The backing sheet of claim 2 wherein the inner layer is a polymer layer and the phase change material is incorporated in the polymer matrix.

4. The backing sheet of claim 2 further comprising thermally conductive fillers incorporated into the outer layer.

5. The backing sheet of claim 1 wherein the backing sheet is a laminate that comprises (a) a first outer layer of weatherable film; (b) at least one mid-layer; and (c) an inner layer, wherein the phase change material is incorporated into the inner layer or applied to the surface of the inner layer.

6. The backing sheet of claim 5 wherein the inner layer comprises of ethylene vinyl acetate (EVA) with a vinyl acetate content of the EVA from about 2 to 33 weight percent.

7. The backing sheet of claim 5 wherein the first outer layer and/or mid-layer comprise thermally conductive fillers.

8. The backing sheet of claim 5 wherein the first outer layer has a thermally conductive coating, a heat rejecting coating, or both.

9. A photovoltaic module comprising:
a backing sheet comprising phase change material incorporated into the backing sheet; and
one or more solar cells, wherein the operating temperature of the solar cells is about the same as the transition temperature of the phase change material.

10. The photovoltaic module of claim 9 wherein the backing sheet comprises at least an inner layer and an outer layer and the phase change material is incorporated into the inner layer.

11. The photovoltaic module of claim 10 wherein the inner layer is a polymer layer and the phase change material is incorporated in the polymer matrix.

12. The photovoltaic module of claim 11 further comprising thermally conductive fillers incorporated into the outer layer.

13. The photovoltaic module of claim 9 wherein the backing sheet is a laminate that comprises (a) a first outer layer of weatherable film; (b) at least one mid-layer; and (c) an inner layer, wherein the phase change material is incorporated into the inner layer or applied to the surface of the inner layer.

14. The photovoltaic module of claim 13 wherein the inner layer comprises of ethylene vinyl acetate (EVA) with a vinyl acetate content of the EVA from about 2 to 33 weight percent.

15. The photovoltaic module of claim 13 wherein the first outer layer and/or mid-layer comprise thermally conductive fillers.

16. The photovoltaic module of claim 13 wherein the first outer layer has a thermally conductive coating, a heat rejecting coating, or both.

17. A method of preventing overheating of solar cells in a photovoltaic module comprising wherein the photovoltaic module comprises a backing sheet comprising:
incorporating one or more phase change materials into the backing sheet.

18. The method of preventing overheating of solar cells in a photovoltaic module of claim 17 further comprising incorporating thermally conductive fillers in the backing sheet or the encapsulant of the photovoltaic module.
